(19) United States
(12) Patent Application Publication
(10) Pub. No.: US 2005/0202614 A1
(43) Pub. Date: Sep. 15, 2005

(54) Laser diode device with nitrogen incorporating barrier

(75) Inventors: Sylvia Spruytte, Palo Alto, CA (US); Michael C. Larson, Walnut Creek, CA (US); James S. Harris, Stanford, CA (US); Christopher Coldren, Sunnyvale, CA (US)

Correspondence Address: Attn: Robert J. Crawford;Crawford Maunu PLLC, Suite 390, 1270 Northland Drive, St. Paul, MN, 55120, US

(73) Assignee: The Board of Trustees of the Leland Stanford Junior University

(21) Appl. No.: 11/075,951

(22) Filed: Mar. 9, 2005

Related U.S. Application Data
(63) Continuation of application No. 09/738,534, filed on Dec. 15, 2000, now abandoned.

(51) Int. Cl. H01L 21/338; H01S 5/00

(52) U.S. Cl. 438/167; 438/21; 438/47

(57) ABSTRACT

In an active region of an optical-electronic semiconductor device, nitrogen is incorporated in a barrier adjacent a GaNAs-based (e.g., GaInNAs) quantum well to improve device performance at wavelength bands above 1.2 microns. In a specific example embodiment, a mirror or cladding layer is grown over the active region in a manner that removes nitrogen complex otherwise present with Ga—N bonds in the active region. The embodiment can be implemented as one of a number of configurations including vertical cavity surface emitting lasers (VCSEL) and edge emitting lasers.

### RELATED PATENT DOCUMENTS

This is a continuation of U.S. patent application Ser. No. 09/738,534, filed on Dec. 15, 2000 (STFD.012PA), which relates to and fully incorporates concurrently-filed U.S. patent application Ser. No. 09/738,907, and entitled “Method for Manufacturing Laser Diode With Nitrogen Incorporating Barrier” (now abandoned). These patent documents are fully incorporated herein by reference priority to which is claimed under 35 U.S.C. § 120 for common subject matter.

### BACKGROUND STATEMENTS

The inventive aspects disclosed herein were made with Government support under contract DAAG55-98-1-0437 awarded by the Department of the Army. The Government has certain rights in these inventive aspects.

### FIELD OF THE INVENTION

The present invention relates generally to optical semiconductor devices and, more specifically, to optical semiconductor devices operable in wavelength bands above 1.2 microns.

### BACKGROUND OF THE INVENTION

Over the past few decades, the field of optics has been used to develop the field of high-speed data communications in wide-ranging technology areas including, among a variety of others, laser printers, optical image storage, submarine optical cable systems, home systems and optical telecommunications. In connection with optical telecommunications, for example, this development has largely displaced the large conical horn-reflector tower-mounted radio antennas with underground optical cables for telecommunication trunks to carry information traffic in the form of optical signals. Currently, quartz glass optical fibers are used to carry high volumes of data generated as light pulses at one end by laser diodes and detected at the other end by optic detectors.

To address the increasing demands for faster-operating and less-expensive communication systems, these quartz-glass optical fibers are being developed to have increasingly larger optical transmission bands, currently with wavelength bands in excess of 1.3-1.5 microns. The appropriate conversion of high-speed data information to optical signals for transmission on such fibers involves presentation of a laser oscillation signal having a wavelength that matches the optical transmission band of the quartz-glass optical fibers. Thus, there have been ongoing efforts to improve the optical semiconductor devices for this conversion in the corresponding wavelength bands.

There have been ongoing efforts to improve the performance of such telecom laser diodes. These efforts have included altering the various interfaces and internal compositions of each layer to tune the devices for minimum cost of fabrication, optimal device performance and reductions in terms of size, heat generation and power consumption. One such effort has lead to the development of GaAs-based Vertical Cavity Surface Emitting Laser (VCSEL) diodes, which are becoming increasingly important in transmitters for high performance data links due to their low cost and ease of fiber coupling. However, the relatively short wavelength of conventional GaAs-based VCSELs (e.g., 820 nm) limits performance due to the wavelength dependent dispersion and loss properties of silica fiber. Additionally, the short wavelength limits the permissible optical power because of eye safety considerations. Longer optical wavelengths can overcome many of these limitations and allow data transmission at higher rates over longer distances.

The thermal stability, or control of the temperature, during the device operation is a serious limitation in the state-of the-art material system for long wavelength emision with GaInAs active regions and InP cladding layers. This temperature control problem is largely due to a relatively small band discontinuity of the conduction band between the GaInAs-based active layer and the surrounding InP cladding layers. The electrons escape easily from the active layer because of the small potential barrier formed by this band discontinuity; consequently, a large drive current is needed to sustain the desired laser oscillation especially at high temperatures when the carriers experience an increased degree of thermal excitation. Because the laser oscillation wavelength can sometimes shift at high temperatures, this phenomena can be a serious problem for many optical communication systems especially those involving signals from multiple fibers that are multiplexed together, such as telecommunication trunks. A multi-heterojunction laser diode grown on a GaAs (Gallium Arsenide) substrate is one common semiconductor device used for this data conversion. Some of the advantages of GaAs based devices are: better thermal stability and easy to manufacture VCSELs. One such GaAs laser diode includes several layers at the center of which is an active region of GaInNAs (Gallium Indium Nitride Arsenide). This active region is used as the main source for the generation of light pulses, and includes outer GaAs contact layers built over a GaAs substrate. To the inside of the outer contact layers and immediately bordering either side of the active layer are upper and lower AlAs (containing Aluminum Arsenide) or AlGaAs (containing Aluminum Gallium Arsenide) cladding regions to contain core light while protecting against surface contaminant scattering. In response to a voltage differential presented via the electrodes at the outer contact layers, holes and electrons are respectively injected into the active layer from the layers above and below. The accumulation of these holes and electrons within the active layer results in their recombination, thereby stimulating the emission of photons and, therefrom, oscillation at a wavelength defined largely by the composition of the active layer.

The longest wavelengths available for devices on GaAs substrates have been typically around 1000 nm and realized using single or multiple-layer InGaAs quantum wells. Growing InGaAs quantum wells on GaAs with optical transitions beyond 1100 nm is difficult because increasing indium content further leads to the formation of crystalline defects and mechanical tension, compression or shear in and around the active layer. This internal stress can be attributable to, among other factors, lattice mismatch between the active region and the substrate and improper temperature control during manufacture of the laser diode device. Inadequate temperature control during manufacture can also result in a higher threshold current of laser oscillation and poor temperature characteristic. Also, the addition of more indium to the quantum well material, in an attempt to achieve longer wavelengths, is a limited approach because both the strain energy and the quantum confinement energy increase with increasing indium content. The quantum confinement energy increases because increasing indium results in smaller effective masses and deeper quantum wells which both serve to push the first quantum confined level to higher energies. Much of the decrease in the bulk energy gap associated with increasing the indium content of the quantum well material is negated and more indium is required to achieve a given wavelength than would be predicted by the bulk bandgap dependence on the indium mole fraction.

The addition of nitrogen to InGaAs quantum wells has been shown to result in the longest wavelengths achievable on GaAs substrates. The role of nitrogen is two fold, the nitrogen causes the bulk bandgap to decrease dramatically and secondly, the smaller lattice constant of GaN results in less strain in GaInNAs compared to InGaAs by itself. Lasers beyond 1.3 μm have been demonstrated with InGaNAs active region grown on GaAs substrates, and GaInNAS VCSELs have been implemented. Both broad-area edge-emitting lasers and long wavelength VCSELs on GaAs substrates employing a single or multiple-layer GaInNAs quantum well active regions result in low threshold current densities. In connection with the present invention, it has also been determined that the GaInNAs system can be advantageous in terms of yield and reproducibility in comparison to the above-discussed arsenide-phosphide system due to critical processing parameters and strongly temperature dependencies. Unfortunately, growing such nitride-arsenides is complicated due to the difficulty of generating a reactive nitrogen source and to the divergent properties of nitride and arsenide materials.

Accordingly, there continues to be a need for improvements in laser diode structures that address a number of issues, including those mentioned above.

### SUMMARY OF THE INVENTION

The present invention is directed to overcoming the above-discussed issues by way of an optical-electronic semiconductor device for applications including those mentioned above, particularly where it is advantageous to implement the active region of such a device with a GaNAs-based (e.g., GaInNAs) quantum well. In such a structure, it has been discovered that incorporating nitrogen in a barrier adjacent the quantum well layer results in improved device performance at wavelength bands above 1.2 microns, and can provide better thermal properties.

One aspect of the invention involves manufacturing an optical-electronic semiconductor device, wherein on a GaAs-based substrate an active region is formed, the active region including a GaNAs-based quantum well layer adjacent a GaAsN-based barrier layer.

In another specific example embodiment of the present invention, the above-characterized optical-electronic semiconductor device is manufactured in the same manner but as a tunnel junction structure instead of forming oppositely-polarized portions above and below the active region.

Yet another aspect of the invention is directed to an optical-electronic semiconductor device having a GaAs-based substrate; an active region over the GaAs-based substrate, the active region including a GaNAs-based quantum well layer adjacent a GaAsN-based barrier layer and including crystal-defect causing impurities. The active region is annealed to remove nitrogen complex otherwise present with Ga—N bonds in the active region. A layer is formed over the annealed active region, and respective opposite portions of the optical-electronic semiconductor device above and below the active region are formed with corresponding electrodes for exciting the active region.

Example implementations of the respective opposite portions are oppositely-polarized materials including, for example, materials over the annealed active region, part of a mirror or cladding region, or another dielectric layer interfacing to a mirror or cladding region.

In other specific example embodiments, a layer such as a mirror or cladding layer is grown over the active region in a manner that removes nitrogen complex otherwise present with Ga—N bonds in the active region.

In yet other embodiments, one or more of the above structures are implemented as vertical cavity surface emitting laser (VCSEL) devices and edge emitting laser devices.

The above summary is not intended to characterize every aspect, or each embodiment, contemplated in connection with the present invention. Other aspects and embodiments will become apparent from the discussion in connection with the figures which are introduced below.

### BRIEF DESCRIPTION OF THE DRAWINGS

Various aspects and advantages of the present invention will become apparent upon reading the following detailed description of various embodiments and upon reference to the drawings in which:

FIG. 1 is a sectional view of a laser diode structure, according to example application of the present invention;

FIG. 2 is a sectional view of an alternative laser diode structure according to the present invention; and

FIG. 3 is graph showing the relationship of nitrogen concentration in a GaNAs film as a function of growth rate, according to the present invention.

While the invention is amenable to various modifications and alternative forms, specifics thereof have been shown by way of example in the drawings and will be described in detail. It should be understood, however, that the intention is not to limit the invention to the particular embodiment described. On the contrary, the invention is to cover all modifications, equivalents, and alternatives falling within the spirit and scope of the invention as defined by the appended claims.

### DETAILED DESCRIPTION

The present invention is believed to be applicable to a variety of circuit arrangements including optical semiconductor devices and, more specifically, to such circuit arrangements operable in wavelength bands above 1.2 microns and having a quantum well active region that is GaNAs-based, i.e., containing gallium, nitrogen and arsenic independent on their composition. A particular specific implementation of the invention has been found to be advantageous for optical semiconductor devices including a GaNAs-based quantum well layer including crystal-defect causing impurities. Various example implementations of the present invention are described below through the following discussion of example applications; those skilled in the art will appreciate that these implementations are merely examples and are not intended to limit the scope of the present invention.

A first example embodiment of present invention is directed to the manufacture of an optical-electronic semiconductor device using a GaAs-based substrate. Formed over the GaAs-based substrate is an active region having a GaNAs-based quantum well layer. For such an implementation it has been discovered that forming a GaNAs-based barrier layer over the GaNAs-based quantum well layer improves operation of the optical-electronic semiconductor device by permitting its operation at a wavelength that is longer relative to an optical-electronic semiconductor device having, for example, simply a GaAs-based barrier layer without the nitrogen species. According to the present invention, this improved operation results from lower QW energy levels for electrons and higher QW energy levels for holes, more limited nitrogen out diffusion from an N-based barrier layer, and improved ability to grow strain-compensated structures.

According to a second example embodiment of present invention, it has been discovered that the above structure is enhanced through the growth of a mirror or cladding layer on top of the active region to anneal the active region and that the growth temperature can be tuned to optimize device performance.

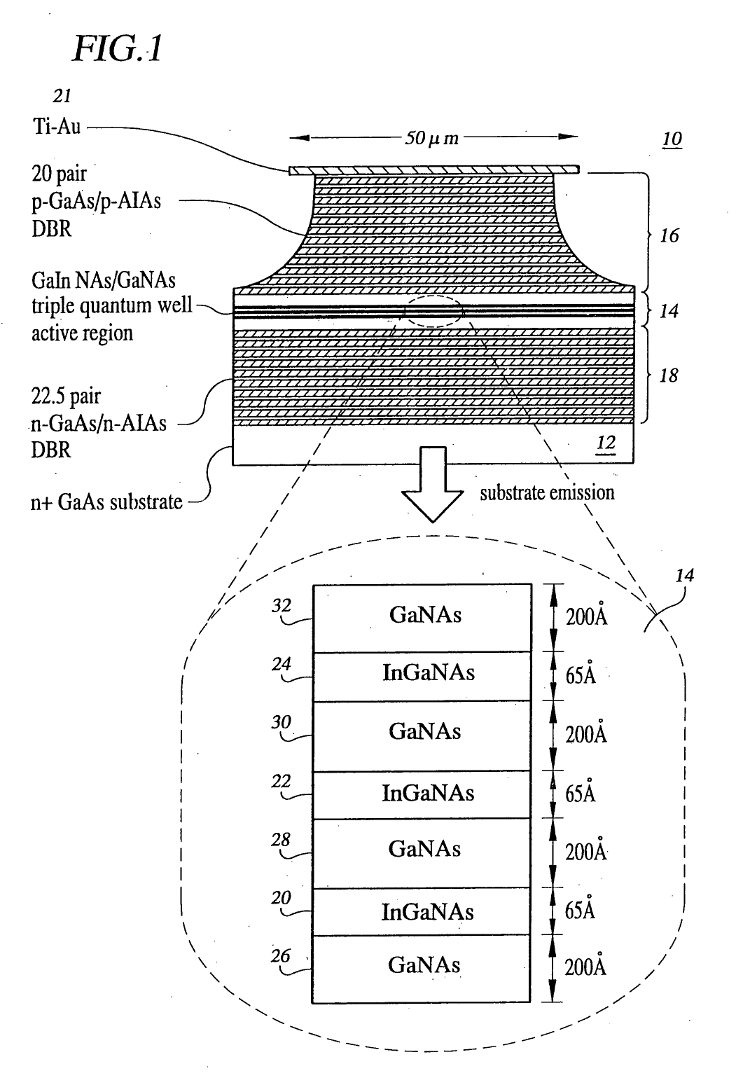

A specific example embodiment of the present invention is illustrated in FIG. 1 as a sectional view of a vertical-cavity surface emitting laser (“VCSEL”) structure 10. The VCSEL structure 10 includes an n+ GaAs substrate 12 upon which various layers are grown to form a GaNAs-based quantum well laser device. While the number of quantum wells is not critical, the structure 10 in this specific example embodiment includes a triple quantum well active region 14 sandwiched between oppositely-doped multilayer reflector structures 16 and 18. In certain environments, these structures are distributed Bragg reflectors, hereinafter referred to as “DBR” structures 16 and 18. The upper DBR structure 16 is a 20 pair p-GaAs/p-AlAs DBR, and can be formed along with the other illustrated layers using conventional processing tools and techniques, for example, as discussed in U.S. Pat. No. 5,689,123, No. 5,904,549 and No. 5,923,691. The lower DBR structure 18 is a 22.5 pair n-GaAs/n-AlAs DBR. To enhance lasing operation, GaInNAs/GaNAs triple quantum well active region 14 can be surrounded by a GaAs cladding to have the cavity length fit to an integral number of half wavelengths. Also, the active region 14 should be at a maximum in the optical field and for a wavelength long cavity this is in the center.

As shown by the arrow emanating from the n+ GaAs substrate 12, the structure 10 is adapted for substrate emission. For exciting the active region 14, an electrode 19 can be formed on the bottom side of the substrate 12 with a window for the substrate emission, and an electrode 21 can be formed on the surface of the DBR structure 16 substrate to form a laser/optical integrated light source. Although not required, the electrode 21 in this example is implemented using a Ti—Au composition for its conductivity attributes.

The triple quantum well active region 14, as magnified in the lower portion of FIG. 1, is shown to include QW layers 20, 22 and 24 respectively between GaNAs-based barrier layers 26, 28, 30 and 32. In one example application, this illustrated structure is formed with each of the respective thicknesses of the QW layers 20, 22 and 24 being 65 Angstroms, and each of the respective thicknesses of the GaNAs-based barrier layers 26, 28, 30 and 32 being 200 Angstroms. An example set of compositions of each of the QW layers and the GaNAs-based barrier layers are In_{0.35}Ga_{0.65}N_{0.02}As_{0.98} and GaN_{0.03}As_{0.97}, respectively.

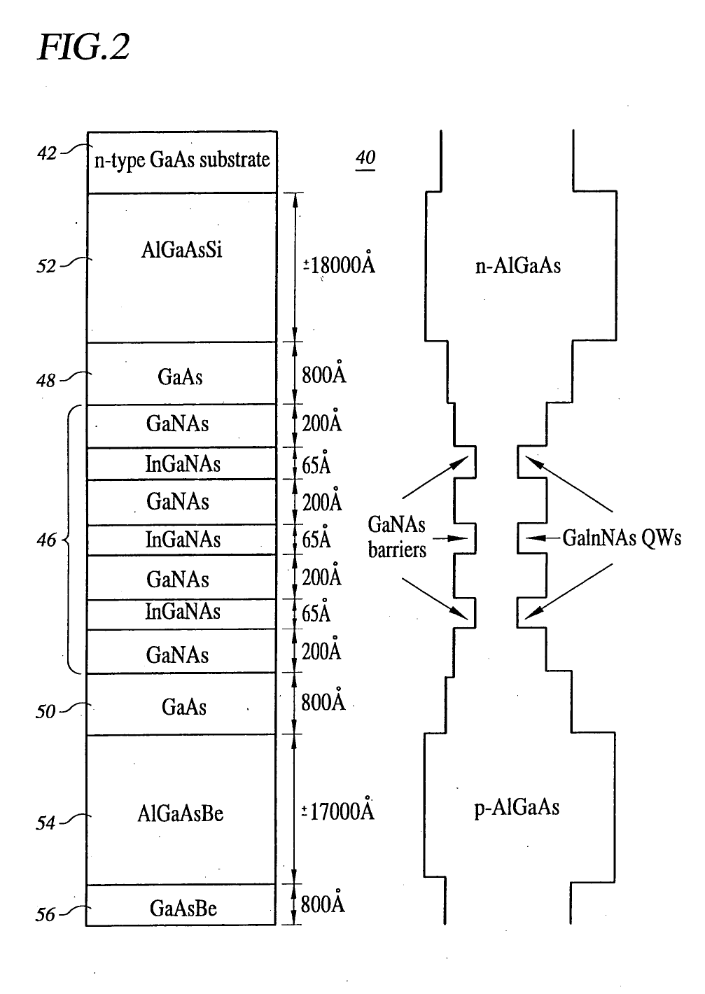

Other specific example embodiments of the present invention are illustrated by way of FIG. 2 which shows a sectional view of an edge-emitting laser structure 40. Like the above-illustrated VCSEL structure 10, the edge-emitting laser structure 40 includes an n-type GaAs substrate 42 upon which various layers are grown to form a GaNAs-based quantum well laser device. In this specific example embodiment, the structure 40 includes a triple quantum well active region 46 which is built using the same thicknesses and layer compositions as discussed above for the triple quantum well active region 14 of FIG. 1.

The illustrated cross section of FIG. 2 also depicts optional GaAs layers 48 and 50 on either side of the active region 46 and to the inside of cladding regions 52 and 54. These GaAs layers 48 and 50, which can also be similarly configured in an alternative embodiment on either side of the active region 14 of FIG. 1, serve to mitigate defects associated with the incorporation of Nitrogen in the barrier layers of the active region. In certain embodiments, the cladding regions 52 and 54 are oppositely-polarized portions, and corresponding electrodes are electrically coupled to the respective oppositely-polarized portions for exciting the active region. In other embodiments, rather than being oppositely-polarized, the cladding regions 52 and 54 are implemented as a tunnel junction structure where the active region is excited using current injection. For further reference on such an approach, reference may be made to Boucart, J. IEEE Photonics Technology Letters, Vol. 11, No. 6, p. 629-31. It will also be appreciated that undoped cladding regions may also be used on either side of the active region in an alternative embodiment for the VCSEL structure 14 of FIG. 1; a related undoped cladding approach is used in conjunction with a VCSEL structure (FIG. 5) described in the above-referenced U.S. Pat. No. 5,923,691.

In a particular example implementation that is consistent with FIG. 2, each of the GaAs layers 48 and 50 is 800 Angstroms in thickness, the cladding region 52 is n-type (for example, about 18000 Angstroms in thickness and composed of Al_{0.33}Ga_{0.67}As 2.10¹⁸/cm³ Si), the cladding region 54 is p-type (for example, about 17000 Angstroms in thickness and composed of Al_{0.33}Ga_{0.67}As 7.10¹⁷/cm³ Be). Contact layer 56 can be implemented, for example, using a 800-Angstrom layer thickness and a composition of GaAs 1.10¹⁹/cm³ Be.

As with the VCSEL structure 10, the active region 46 can be excited using electrodes (not shown) on either side of the illustrated structure.

Instead of the triple-layer approach depicted in FIGS. 1 and 2, in other embodiments for the VCSEL and edge-emitting structures of FIGS. 1 and 2, a single QW layer or other multiple QW layers are arranged between the GaNAs-based barrier layers.

Each of the above-discussed approaches relates to the discovery herewith that the photoluminescence (PL) of a GaNAs quantum well or a GaInNAs quantum well increases drastically and shifts to shorter wavelengths when annealing. The increase in PL efficiency results from a decrease in non-radiative recombination centers. As the impurity concentration in our films is low, the result is crystal defects associated with the nitrogen incorporation. regard, nitrogen exists in one configuration involving a Ga—N bond and another configuration that is a nitrogen-complex in which nitrogen is less strongly bonded to gallium atoms and that is removed by annealing, e.g., for 30 seconds at 775° C. under an N₂ ambient with a proximity cap. Further, it has been observed that the crystal quality of GaNAs films increases with annealing, and that the InGaNAs quantum wells emitting at 1.3 μm are sharp and dislocation-free.

By optimizing growth and anneal, low threshold edge emitting lasers and vertical cavity surface emitting lasers are realizable with GaInNAs active regions emitting at wavelengths in excess of 1.2-1.3 μm. For example, PL at 1.33 μm and broad area lasers emitting at 1.3 μm are realizable by using previously-known GaInNAs compositions but imbedding the QW's in GaNAs barriers instead of GaAs barriers. These longer wavelengths are due to decreased potential barriers for the well and decreased nitrogen out-diffusion during anneal and/or cladding layer growth. Additional advantages of the GaNAs barriers include being able to grow strain compensated structures and obtaining better thermal properties.

In one implementation, the growth of Nitride-Arsenides is performed in a Varian Gen II system using elemental sources. Group III fluxes are provided by thermal effusion cells, dimeric arsenic is provided by a thermal cracker, and reactive nitrogen is provided by an RF plasma cell. The plasma conditions that maximize the amount of atomic nitrogen versus molecular nitrogen can be determined using the emission spectrum of the plasma.

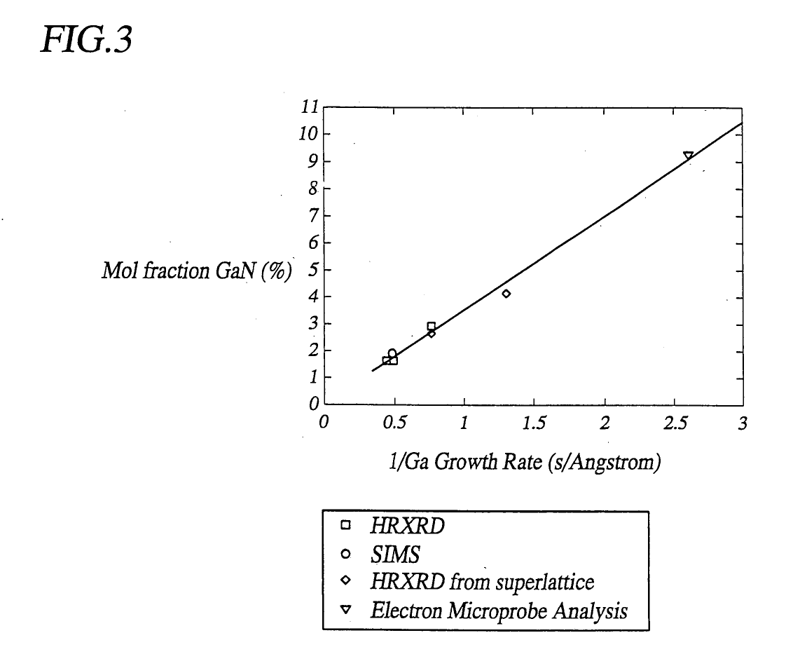

As shown in FIG. 3, the group III growth rate controls the GaNAs film's nitrogen concentration, where the nitrogen plasma is operated at 300 Watts with a nitrogen flow of 0.25 sccm and measured using HRXRD, SIMS and electron microprobe analysis. In this implementation, the nitrogen concentration is inversely proportional to the GaAs growth rate because the sticking coefficient of atomic nitrogen is unity and the amount of N₂ formation is negligible at the low growth temperatures used. Thus, the GaInNAs system is advantageous in terms of yield and reproducibility compared to the arsenide-phosphide system where a group V flux control is critical and strongly dependent on temperature.

Relating to each of the above embodiments, other aspects, discoveries, advantages and embodiments realized in connection with the present invention are characterized in the above-referenced patent document and in a 15-page article attached hereto as an appendix and entitled, “Broad area lasers with GaInNAs QWs and GaNAs Barriers” by Sylvia Spruytte et al., and incorporated by reference in its entirety.

The various embodiments described above are provided by way of illustration only and should not be construed to limit the invention. Based on the above discussion and illustrations, those skilled in the art will readily recognize that various modifications and changes may be made to the present invention without strictly following the exemplary embodiments and applications illustrated and described herein. Such changes include, but are not necessarily limited to variations of the example compositions and thicknesses, variations of some of the process steps used to achieve less than all of the advantages described, and various application-directed alterations for circuit integration implementations such as described and/or illustrated for example in connection with the illustrated embodiments of the other above-mentioned patents. Such modifications and changes do not depart from the true spirit and scope of the present invention that is set forth in the following claims.

1. (canceled)

2. A method for manufacturing an optical-electronic semiconductor device, comprising:
providing a GaAs-based substrate; and
using molecular beam epitaxy to form an active region over the GaAs-based substrate, the active region including a GaNAs-based quantum well layer adjacent a GaNAs-based barrier layer and including crystal-defect causing impurities and Ga—N bonds but not including nitrogen complex configurations.

3. The method of claim 2, wherein using molecular beam epitaxy to form an active region includes forming an active region having multiple GaNAs-based quantum well layers, each of the GaNAs-based quantum well layers located between a pair of GaNAs-based barrier layers.

4. The method of claim 3, wherein using molecular beam epitaxy to form an active region includes forming each GaNAs-based quantum well layer composed of GaInNAs and each GaNAs-based barrier layer composed of GaNAs.

5. The method of claim 2, wherein using molecular beam epitaxy to form an active region includes forming the GaNAs-based quantum well layer composed of GaInNAs and the GaNAs-based barrier layer composed of GaNAs.

6. The method of claim 5, wherein using molecular beam epitaxy to form an active region includes forming another layer between a GaInNAs quantum well layer and the GaNAs-based barrier layer.

7. The method of claim 2, further including the step of forming oppositely-polarized portions of the optical-electronic semiconductor device above and below the active region.

8. The method of claim 7, further including the step of forming electrodes electrically coupled to the respective oppositely-polarized portions and adapted for exciting the active region.

9. The method of claim 2, further including the step of forming cladding regions implemented about the active region as a tunnel junction structure and further including the step of exciting the active region using current injection.

10. A method for manufacturing an optical-electronic semiconductor device, comprising:
providing a GaAs-based substrate;
using molecular beam epitaxy to form an active region over the GaAs-based substrate, the active region including a GaNAs-based quantum well layer adjacent a GaNAs-based barrier layer and including crystal-defect causing impurities;
annealing the active region to remove nitrogen complex configurations otherwise present with Ga—N bonds in the active region; and
forming oppositely-polarized portions of the optical-electronic semiconductor device above and below the active region, and corresponding electrodes electrically coupled to the respective oppositely-polarized portions adapted for exciting the active region.

11. The method of claim 10, further including the step of forming a layer over the annealed active region where the layer over the annealed active region and the annealed active region are configured with a minimum number of non-radiative recombination centers to optimize device performance.

12. The method of claim 10, wherein using molecular beam epitaxy to form the active region includes forming multiple GaNAs-based quantum well layers, each of the GaNAs-based quantum well layers located between a pair of GaNAs-based barrier layers.

13. The method of claim 10, wherein using molecular beam epitaxy to form an active region includes forming the GaNAs-based quantum well layer composed of GaInNAs and the GaNAs-based barrier layer composed of GaNAs.

14. The method of claim 13, further including the step of forming a layer over and immediately adjacent the annealed active region.

15. The method of claim 10, further including the step of forming a layer over and immediately adjacent the annealed active region and wherein using molecular beam epitaxy to form an active region includes forming the GaNAs-based barrier layer and the GaNAs-based quantum well layer having respective thicknesses and the thickness of the GaNAs-based barrier layer is not more than about 5 times the thickness of the GaNAs-based quantum well layer.

16. The method of claim 10, further including the step of forming a cladding layer over and immediately adjacent the annealed active region.

17. The method of claim 10, further including the step of forming a mirror layer over and immediately adjacent the annealed active region.

18. The method of claim 10, wherein using molecular beam epitaxy to form an active region includes forming the GaNAs-based quantum well layer and the GaNAs-based barrier layer respectively composed of GaInNAs and GaNAs.

19. The method of claim 18, wherein using molecular beam epitaxy to form an active region includes forming the active region having a thin GaAs layer between a GaInNAs quantum well layer and the GaNAs-based barrier layer.

20. The device of claim 19, further including first and second mirror regions respectively above and below the active region, and being configured with the corresponding electrodes as a vertical cavity surface emitting optical-electronic semiconductor device.

21. A method of manufacturing a vertical cavity surface emitting optical-electronic semiconductor device, comprising:
providing a GaAs-based substrate;
forming a first DBR region over the GaAs-based substrate;
using molecular beam epitaxy to form an active region over the first DBR region, the active region including a GaInNAs quantum well layer adjacent a GaAsN barrier layer and including crystal-defect causing impurities;
annealing the active region to remove nitrogen complex configurations otherwise present with Ga—N bonds in the active region;
forming a second DBR region over the annealed active region, the first and second DBR regions being oppositely-polarized; and
forming oppositely-polarized electrodes electrically coupled to the correspondingly respective first and second DBR regions, the electrodes being adapted for exciting the active region and causing emissions through the GaAs-based substrate.

22. A method of manufacturing a VCSEL optical-electronic semiconductor device, comprising:
providing a GaAs-based substrate;
using molecular beam epitaxy to form a multiple quantum well active region over the GaAs-based substrate, the active region including multiple GaNas-based quantum well layers and including crystal-defect causing impurities and Ga—N bonds but not including nitrogen complex configurations, each of the well layers being surrounded by a pair of adjacent GaNAs-based barrier layers; and
forming mirror portions on either side of the multiple quantum well active region, the mirror portions adapted for exciting the active region.

23. The method of claim 22, wherein forming mirror portions includes forming mirror portions that are oppositely-doped DBR sections.

24. The method of claim 22, wherein forming mirror portions includes forming mirror portions that are oppositely-doped DBR sections, and wherein using molecular beam epitaxy to form the multiple quantum well active region includes forming the active region including crystal-defect causing impurities and Ga—N bonds, but does not including nitrogen complex configurations.

25. A method of manufacturing an edge-emitter optical-electronic semiconductor device, comprising:
providing a GaAs-based substrate;
using molecular beam epitaxy to form a multiple quantum well active region over the GaAs-based substrate, the active region including multiple GaNAs-based quantum well layer and including crystal-defect causing impurities and Ga—N bonds but not including nitrogen complex configurations, each of the well layers being surrounded by a pair of adjacent GaNAs-based barrier layers; and
forming cladding portions electrically coupled to the multiple quantum well active region and adapted for exciting the active region.

26. The method of claim 25, further including the step of providing a GaAs-based layer on one side of the multiple quantum well active region between the multiple quantum well active region and one of the cladding portions, and another GaAs-based layer on another side of the multiple quantum well active region between the multiple quantum well active region and another of the cladding portions.
